(19) United States
(12) Patent Application Publication
(10) Pub. No.: US 2026/0328880 A1
(43) Pub. Date: Oct. 22, 2026

(54) SYSTEMS, APPARATUSES, AND METHODS FOR PERFORMING MAGNETIC RESONANCE IMAGING USING ARTERIAL-SPIN LABELING

(71) Applicant: Siemens Healthineers AG, Forchheim (DE)

(72) Inventor: Yulin Chang, Belmont, MA (US)

(21) Appl. No.: 19/185,301

(22) Filed: Apr. 22, 2025

(51) Int. Cl. G01R 33/561; G01R 33/56; G01R 33/563

(52) U.S. Cl. CPC G01R 33/5616; G01R 33/5608; G01R 33/56366

(57) ABSTRACT

A system for performing magnetic resonance (“MR”) imaging using arterial-spin labeling (“ASL”) includes at least one memory configured to store instructions and at least one processor configured to execute the instructions to cause the system to perform a pseudo-continuous ASL (“pCASL”) phase, the pCASL phase being at least one of a pCASL labelling phase or a pCASL control phase and perform an image acquisition after the pCASL phase using multi-echo echo planar imaging (“EPI”).

### TECHNICAL FIELD

The present disclosure relates to systems, apparatuses, and/or methods for performing magnetic resonance (“MR”) imaging using arterial-spin labeling (“ASL”).

### BACKGROUND

Arterial-spin labeling (“ASL”) is a non-invasive magnetic resonance (“MR”) technique used to measure blood perfusion by magnetically labeling water nuclei in blood before blood perfuses into tissue. ASL includes pulsed ASL (“PASL”) where blood surrounding an imaging volume is labeled and continuous ASL (“CASL”) or pseudo-continuous ASL (“pCASL”) where blood up-stream of an imaging volume is labeled using flow-driven adiabatic passage.

### SUMMARY

At least one example embodiment relates to a method for performing magnetic resonance (“MR”) imaging using arterial-spin labeling (“ASL”). The method may include performing a pseudo-continuous ASL (“pCASL”) phase, the pCASL phase being at least one of a pCASL labelling phase or a pCASL control phase and performing an image acquisition after the pCASL phase using multi-echo echo planar imaging (“EPI”).

In at least one example embodiment, the multi-echo EPI includes at least two echo acquisitions.

In at least one example embodiment, the performing the image acquisition after the pCASL phase using the multi-echo EPI may include performing a first echo acquisition, rewinding k-space after the first echo acquisition, and performing a second echo acquisition.

In at least one example embodiment, a readout (“RO”) gradient may be continuous across all echoes of the multi-echo EPI.

In at least one example embodiment, the method may further include obtaining an image for each echo of the multi-echo EPI and combining the images for each echo of the multi-echo EPI to obtain a perfusion-weighted image. In at least one example embodiment, the perfusion-weighted image may be a weighted combination of the images from each echo of the image acquisition using multi-echo EPI. In at least one example embodiment, an image from a first echo acquisition may be weighed higher than other images of the multi-echo EPI for the perfusion-weighted image.

Also described herein is a system for performing magnetic resonance (“MR”) imaging using arterial-spin labeling (“ASL”). The system may include at least one memory configured to store instructions and at least one processor configured to execute the instructions to cause the system to perform a pseudo-continuous ASL (“pCASL”) phase, the pCASL phase being at least one of a pCASL labelling phase or a pCASL control phase and perform an image acquisition after the pCASL phase using multi-echo echo planar imaging (“EPI”).

In at least one example embodiment, the multi-echo EPI may include at least two echo acquisitions.

In at least one example embodiment, the processor may be configured to cause the system to, for the performing the image acquisition after the pCASL using the multi-echo EPI, perform a first echo acquisition, rewind k-space after the first echo acquisition, and perform a second echo acquisition.

In at least one example embodiment, a readout (“RO”) gradient may be continuous across all echoes of the multi-echo EPI.

In at least one example embodiment, the processor may be further configured to cause the system to obtain an image for each echo of the multi-echo EPI, and combine the images for each echo of the multi-echo EPI to obtain a perfusion-weighted image. In at least one example embodiment, the perfusion-weighted image may be a weighted combination of the images from each echo of the image acquisition using multi-echo EPI. In at least one example embodiment, an image from a first echo acquisition may be weighed higher than other images of the multi-echo EPI for the perfusion-weighted image.

Also described herein is a non-transitory computer readable medium storing computer-executable instruction that, when executed by at least one processor of a system, may cause the system to perform a method for performing magnetic resonance (“MR”) imaging using arterial-spin labeling (“ASL”). The method may include performing a pseudo-continuous ASL (“pCASL”) phase, the pCASL phase being at least one of a pCASL labelling phase or a pCASL control phase; and performing an image acquisition after the pCASL phase using multi-echo echo planar imaging (“EPI”).

In at least one example embodiment, the multi-echo EPI may include at least two echo acquisitions.

In at least one example embodiment, the performing the image acquisition after the pCASL phase using the multi-echo EPI may include performing a first echo acquisition, rewinding k-space after the first echo acquisition, and performing a second echo acquisition.

In at least one example embodiment, a readout (“RO”) gradient may be continuous across all echoes of the multi-echo EPI.

In at least one example embodiment, the method may further include obtaining an image for each echo of the multi-echo EPI and combining the images for each echo of the multi-echo EPI to obtain a perfusion-weighted image. In at least one example embodiment, the perfusion-weighted image may be a weighted combination of the images from each echo of the image acquisition using multi-echo EPI and an image from a first echo acquisition may be weighed higher than other images of the multi-echo EPI for the perfusion-weighted image.

### BRIEF DESCRIPTION OF THE DRAWINGS

The various features and advantages of the non-limiting embodiments herein may become more apparent upon review of the detailed description in conjunction with the accompanying drawings. The accompanying drawings are merely provided for illustrative purposes and should not be interpreted to limit the scope of the claims. The accompanying drawings are not to be considered as drawn to scale unless explicitly noted. For purposes of clarity, various dimensions of the drawings may have been exaggerated.

FIG. 1A is an illustration of a system for implementing methods according to example embodiments.

FIG. 1B is a block diagram illustrating an example embodiment of the system shown in FIG. 1A.

FIG. 2 is a pCASL sequence block diagram illustrating a gap between an end of imaging and a next repetition time in accordance with at least one example embodiment.

FIG. 3 illustrates three echoes of a multi-echo echo planar imaging sequence in accordance with at least one example embodiment.

FIG. 4 is a pCASL sequence block diagram illustrating a reduced gap from the pCASL sequence block diagram of FIG. 2 in accordance with at least one example embodiment.

FIG. 5 illustrates raw images obtained by three echoes of a multi-echo echo planar imaging sequence in accordance with at least one example embodiment.

FIG. 6 illustrates perfusion weighted images of the raw images of FIG. 5 and a sum of the perfusion weighted images in accordance with at least one example embodiment.

FIG. 7 illustrates a method for performing magnetic resonance imaging using arterial-spin labelling in accordance with at least one example embodiment.

FIG. 8 illustrates an example embodiment of a method of performing multi-echo echo planar imaging at S704 in FIG. 7.

FIG. 9 illustrates a method of determining a perfusion-weighted image in accordance with at least one example embodiment.

### DETAILED DESCRIPTION OF EXAMPLE EMBODIMENTS

Independent of the grammatical term usage, individuals with male, female or other gender identities are included within the term.

Some detailed example embodiments are disclosed herein. However, specific structural and functional details disclosed herein are merely representative for purposes of describing some example embodiments. Example embodiments may, however, be embodied in many alternate forms and should not be construed as limited to only example embodiments set forth herein.

Accordingly, while example embodiments are capable of various modifications and alternative forms, example embodiments thereof are shown by way of example in the drawings and will herein be described in detail. It should be understood, however, that there is no intent to limit an example embodiment to the particular forms disclosed, but to the contrary, example embodiments are to cover all modifications, combinations, equivalents, and alternatives falling within the scope of an example embodiment. Like numbers refer to like elements throughout the description of the figures.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It should be understood that, although the terms first, second, third, etc. may be used herein to describe various elements, regions, layers and/or sections, these elements, regions, layers, and/or sections should not be limited by these terms. These terms are only used to distinguish one element, region, layer, or section from another region, layer, or section. Thus, a first element, region, layer, or section discussed below could be termed a second element, region, layer, or section without departing from the teachings of example embodiment.

The terminology used herein is for the purpose of describing various example embodiment only and is not intended to be limiting of example embodiment. As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, and/or elements, but do not preclude the presence or addition of one or more other features, integers, steps, operations, elements and/or groups thereof.

When the words “about” and “substantially” are used in this specification in connection with a numerical value, it is intended that the associated numerical value include a tolerance of ±10% around the stated numerical value, unless otherwise explicitly defined. Moreover, when the terms “generally” or “substantially” are used in connection with geometric shapes, it is intended that precision of the geometric shape is not required but that latitude for the shape is within the scope of the disclosure. Furthermore, regardless of whether numerical values or shapes are modified as “about,” “generally,” or “substantially,” it will be understood that these values and shapes should be construed as including a manufacturing or operational tolerance (e.g., ±10%) around the stated numerical values or shapes.

Unless otherwise defined, all terms (including technical and scientific terms) used herein have the same meaning as commonly understood by one of ordinary skill in the art to which example embodiment belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Arterial-spin labelling is a non-invasive magnetic resonance (“MR”) technique that may be used for measuring blood perfusion. ASL may include pulsed ASL (“PASL”) where blood surrounding an imaging volume is labeled and continuous ASL (“CASL”) or pseudo-continuous ASL (“pCASL”) where blood up-stream of an imaging volume is labeled using flow-driven adiabatic passage. ASL is a signal to noise ratio (“SNR”) limited technique due to the relatively small amount of blood in the brain that can be used to create contrast. In at least one example embodiment, multi-echo echo planar imaging (“EPI”) is used to acquire additional images during an imaging acquisition which may improve imaging by enhancing the SNR of the ASL.

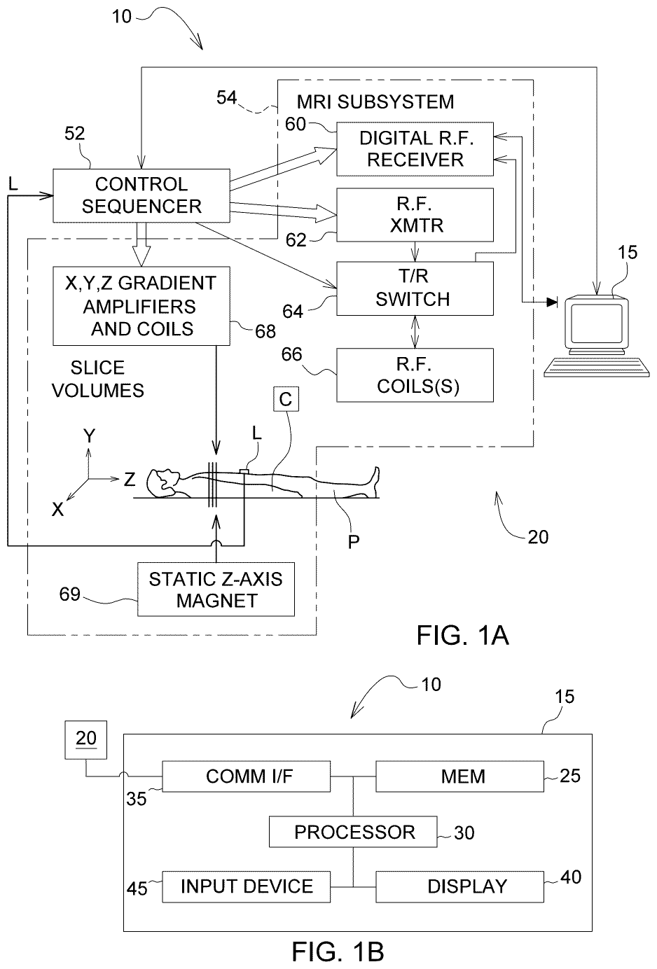

FIG. 1A is an illustration of a system for implementing methods according to example embodiments described herein. FIG. 1B is a block diagram illustrating an example embodiment of the system shown in FIG. 1A. Although one or more example embodiments may be described herein with regard to the systems shown in FIGS. 1A and 1B, example embodiments should not be limited to these examples.

Referring to FIGS. 1A and 1B, a system 10 may include an information processing device 15 and an acquisition device 20. The acquisition device 20 includes a magnetic resonance imaging (“MRI”) real-time control sequencer 52 and an MRI subsystem 54. The MRI subsystem 54 may include XYZ magnetic gradient coils and associated amplifiers 68, a static Z-axis magnet 69, a digital radiofrequency (“RF”) transmitter 62, a digital RF receiver 60, a transmit/receive switch 64, and RF coil(s) 66. The acquisition device 20 may include additional or fewer components in some example embodiments, and may be configured to image a patient.

The MRI subsystem 54 may be controlled in real-time by the MRI real-time control sequencer 52 to generate and measure magnetic field and radio frequency emissions that stimulate nuclear magnetic resonance (“NMR”) phenomena in an object P (e.g., a human or other living body) to be imaged.

The information processing device 15 may implement a method for processing medical data, such as medical image data. As discussed in more detail below, one or more information processing devices such as the information processing device 15 may be configured to implement any or all of the example embodiments described herein.

In FIGS. 1A and 1B, the acquisition device 20 is shown as a separate unit from the information processing device 15. It is, however, possible to integrate the information processing device 15 as part of the acquisition device 20.

The information processing device 15 may include at least one memory 25, processing circuitry including at least one processor 30, at least one communication interface 35 and/or an input device 40. The at least one memory 25 may include various special purpose program code including computer executable instructions which may cause the at least one processor 30 of the information processing device 15 to perform one or more of the methods according to example embodiments described herein. The acquisition device 20 may provide the medical data to the information processing device 15 via the input device 40. In some example embodiments, the information processing device 15 may additionally include a display 45 that may be configured to output information about one or more of an imaging process, the information processing device 15, or the acquisition device 20.

As will be appreciated, depending on the implementation of the system 10, the system 10 may include additional components. However, it is not necessary that all of these generally conventional components be shown in order to disclose the illustrative example embodiment. For example purposes, the system 10 will be discussed with regard to the at least one processor 30. However, it should be understood that the system 10 may include one or more processors or other processing circuitry, such as one or more Application Specific Integrated Circuits (“ASICs).

The at least one processor 30 may include, but is not limited to, a central processing unit (“CPU”), an arithmetic logic unit (“ALU”), a graphics processing unit (“GPU”), an application processor (“AP”), a digital signal processor (“DSP”), a microcomputer, a field programmable gate array (“FPGA”), and programmable logic unit, ASIC, a neural network processing unit (“NPU”), an Electronic Control Unit (“ECU”), a quantum computer, and the like. In some example embodiments, the processing circuitry may include a non-transitory computer readable storage medium or device (e.g., memory), for example a solid state drive (“SSD”), storing a program of instructions, and a processor (e.g., CPU) configured to execute the program of instructions to implement the functionality and/or methods performed by some or all of the systems according to any of the example embodiments.

The at least one memory 25 may be a computer readable storage medium that generally includes a random access memory (“RAM”), read only memory (“ROM”), and/or a permanent mass storage device, such as a disk drive. The at least one memory 25 may also store an operating system and any other routines/modules/applications for providing the functionalities of the system 10 to be executed by the at least one processor 30. These software components may also be loaded from a separate computer readable storage medium into the at least one using a drive mechanism (not shown). Such separate computer readable storage medium may include a disc, tape, DVD/CD-ROM drive, memory card, or other like computer readable storage medium (not shown). In some example embodiments, software components may be loaded into the at least one memory 25 via one of the at least one communication interface 35, rather than via a computer readable storage medium.

The at least one processor 30 or other processing circuitry may be configured to carry out instructions of a computer program by performing the arithmetical, logical, and input/output operations of the system. Instructions may be provided to the at least one processor 30 by the at least one memory 25.

The at least one communication interface 35 may be wired and may include components that interface the at least one processor 30 with the other input/output components. As will be understood, the at least one communication interface 35 and programs stored in the at least one memory 25 to set forth the special purpose functionalities of the system 10 will vary depending on the implementation of the system 10.

The at least one communication interface 35 may also include one or more user input devices (e.g., a keyboard, a keypad, a mouse, or the like) and user output devices (e.g., a display, a speaker, or the like).

As disclosed herein, the term “storage medium,” “computer readable storage medium” or “non-transitory computer readable storage medium” may represent one or more devices for storing data, including ROM, RAM, magnetic RAM, core memory, magnetic disk storage mediums, optical storage mediums, flash memory devices and/or other tangible machine-readable mediums for storing information. The term “computer-readable medium” may include, but is not limited to, portable or fixed storage devices, optical storage devices, and various other mediums capable of storing, containing or carrying instruction(s) and/or data.

Furthermore, example embodiments may be implemented by hardware, software, firmware, middleware, microcode, hardware description languages, or any combination thereof. When implemented in software, firmware, middleware or microcode, the program code or code segments to perform the necessary tasks may be stored in a machine or computer readable medium such as a computer readable storage medium. When implemented in software, a processor or processors will perform the necessary tasks. For example, as mentioned above, according to one or more example embodiments, at least one memory may include or store a computer program or computer program code, and the at least one memory and the computer program code may be configured to, with at least one processor, the methods described herein. Additionally, the processor, memory and example algorithms, encoded as computer program code, serve as means for providing or causing performance of operations discussed herein. At least one other example embodiment may include a computer program including program segments or instructions that, when executed by at least one processor of a system, cause the system to perform the functions and methods described herein.

A code segment of a computer program may represent a procedure, function, subprogram, program, routine, subroutine, module, software package, class, or any combination of instructions, data structures or program statements. A code segment may be coupled to another code segment or a hardware circuit by passing and/or receiving information, data, arguments, parameters or memory contents. Information, arguments, parameters, data, etc. may be passed, forwarded, or transmitted via any suitable technique including memory sharing, message passing, token passing, network transmission, etc.

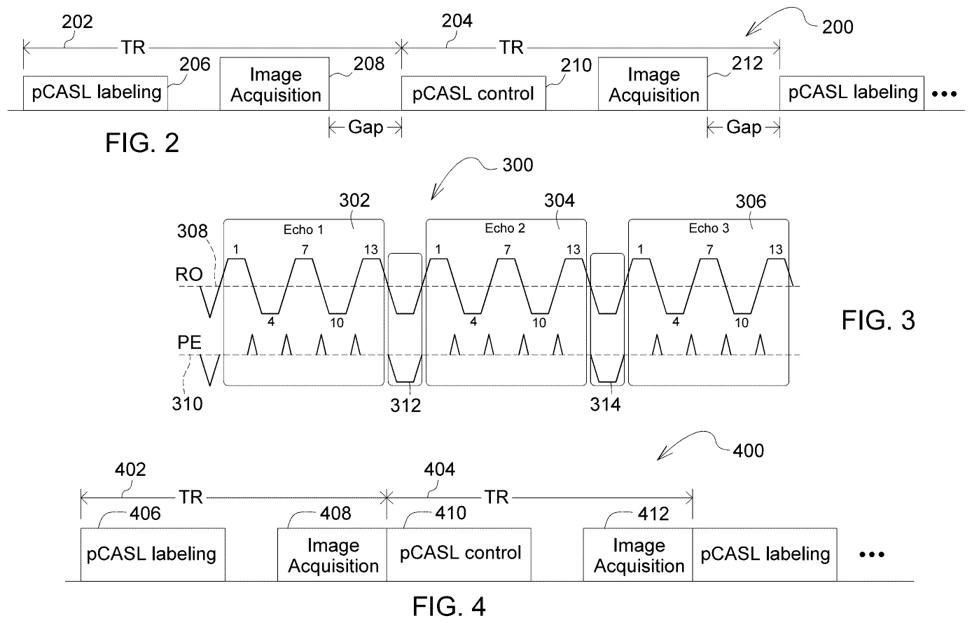

FIGS. 2-9 will be discussed herein with respect to the system 10 of FIGS. 1A and 1B. It should be understood, however, that example embodiments should not be limited to those described herein.

FIG. 2 illustrates an example embodiment of a pCASL sequence block diagram 200 for an MR imaging procedure using ASL. The pCASL sequence block diagram 200 is background information for the systems and methods described herein. The ASL of the pCASL sequence block diagram 200 is pCASL.

Referring to FIG. 2, the pCASL sequence block diagram 200 includes a first repetition time (“TR”) 202 and a second TR 204. Although two TRs are shown in the pCASL sequence block diagram 200, it should be understood that there may be additional TRs for an MR imaging procedure using ASL.

In the first TR 202, the at least one processor 30 may perform a pCASL labelling phase 206. A pCASL labelling phase may involve labelling blood of a patient or subject up-stream of an imaging volume. In particular, the at least one processor 30 may cause the system 10 to label water nuclei in blood before the blood perfuses into tissue by applying an RF pulse which may invert an arterial spin of the blood. The pCASL labelling phase aims to label as much blood as possible. However, if the pCASL labelling phase is extended, the TR may need to be extended to avoid subjecting the patient or subject to excess radiation.

Following the pCASL labelling phase 206, the at least one processor 30 may perform a first image acquisition 208. The first image acquisition 208 may be a fast acquisition technique such as EPI. To reduce a time of the first image acquisition 208, the EPI may be accelerated which may reduce distortion but may also reduce SNR.

The second TR 204 of the pCASL sequence block diagram 200 includes a pCASL control phase 210 followed by a second image acquisition 212. The pCASL control phase 210 may apply RF pulses with alternating phases to prevent the arterial spin of the blood from being flipped. The second image acquisition 212 may be the same as or similar to the first image acquisition 208 of the first TR 202.

Following the second TR 204, an additional TR may be performed that includes a pCASL labelling phase. TRs following the first TR and the second TR may alternate between including pCASL labelling phases and pCASL control phases similar to the first TR 202 and the second TR 204.

As described above, if the pCASL labelling phase 206, or the pCASL control phase 210, is extended, the TR may be extended which may result in a gap following the first image acquisition 208. This may result in a less efficient ASL procedure than if a gap did not follow the first image acquisition 208. The systems and methods described herein provide an improved MR imaging technique which allows a desired pCASL labelling phase with a longer imaging acquisition which results in a smaller gap between adjacent repetition times. The systems and methods described herein may also allow an imaging acquisition to more efficiently cover the whole brain, minimize image distortion, and/or maintain a desired readout duration which may provide improved MR imaging.

FIG. 3 is diagram 300 of an example embodiment of a gapless multi-echo EPI sequence for use in an MR imaging acquisition.

Referring to FIG. 3, the diagram 300 includes three echoes that may be part of a multi-echo EPI imaging acquisition. In particular, a first echo 302 may be followed by a second echo 304, which may be followed by a third echo 306. The image acquisition including the three echoes may be considered gapless because the second echo 304 may follow the first echo 302 without a gap and the third echo 306 may follow the second echo 304 without a gap.

For an image acquisition, such as that shown in the diagram 300, there may be a readout gradient 308 and a phase encoding gradient 310. The readout gradient 308 and the phase encoding gradient 310 of each echo of the diagram 300 may each traverse an entirety of k-space for a particular image acquisition. As shown in FIG. 3, k-space may be rewound at portion 312 and portion 314. This may allow the entirety of k-space to be traversed for each echo.

As is generally known, rewinding k-space involves strategically filling the k-space matrix in a non-sequential manner to allow for the collection of data from k-space in a different order than the typical line-by-line acquisition. Because rewinding k-space is generally known, a detailed discussion is omitted.

A multi-echo EPI imaging acquisition may acquire a similar amount of data as a single EPI imaging acquisition in at least some example embodiments. Thus, images from a multi-echo EPI and a single echo EPI may have similar SNR. However, the multi-echo EPI imaging acquisition may be accelerated because the images from the multi-echo EPI may have a higher effective phase encoding bandwidth, which may result in images with less distortion than images from a fully sampled, single EPI image acquisition. Thus, using multi-echo EPI may result in images that maintain a total SNR while reducing image distortion as compared with images of a single echo EPI.

In at least one example embodiment, an image may be obtained from each echo of the multi-echo EPI. The images obtained from multi-echo EPI may be combined in, for example, a weighted combination. Additional details of the resultant images from multi-echo EPI are described below.

Although three echoes are illustrated in the diagram 300, an imaging acquisition that utilizes multi-echo imaging may include at least two echoes. For example multi-echo EPI may include two, three, or four echoes. In some example embodiments, additional echoes may be included.

FIG. 4 illustrates an example embodiment of a pCASL sequence block diagram 400 for an MR imaging procedure using ASL with multi-echo EPI during imaging acquisition.

Referring to FIG. 4, the pCASL sequence block diagram 400 is similar to the pCASL sequence block diagram 200 of FIG. 2 as a first TR 402 includes a pCASL labelling phase 406 followed by a first image acquisition 408 and a second TR 404 includes a pCASL control phase 410 followed by a second image acquisition 412. However, the first image acquisition 408 of the first TR 402 and the second image acquisition 412 of the second TR 404 are multi-echo EPI image acquisitions which are longer than the single echo EPI image acquisitions as shown in FIG. 2.

As shown in FIG. 4, there is no gap between the first image acquisition 408 and the pCASL control phase 410 of the second TR 404. While shown as gapless, it should be understood that there may be some time between the first image acquisition 408 and the pCASL control phase 410 of the second TR 404 but the time is reduced from the gap shown between the first image acquisition 208 and the pCASL control phase 210 of the second TR 204 of FIG. 2. In particular, for example, the gap in FIG. 2 may be about 1 second or between about 100 ms to a few seconds. The time between the first image acquisition 408 and the pCASL control phase 410 of the second TR 404 may be smaller than the time between the first image acquisition 208 and the pCASL control phase 210 of the second TR 204 of FIG. 2 because the first image acquisition 408 may be longer than the first image acquisition 208. In particular, a multi-echo EPI imaging acquisition may be longer than a single echo EPI imaging acquisition and thus, the gap of FIG. 2 is being more efficiently used by acquiring additional imaging data via the multi-echo EPI imaging as described herein.

Similar to FIG. 2, the first TR 402 and the second TR 404 may be repeated and thus an imaging acquisition following a pCASL control phase may be extended and may end proximate to a beginning of a next pCASL labelling phase.

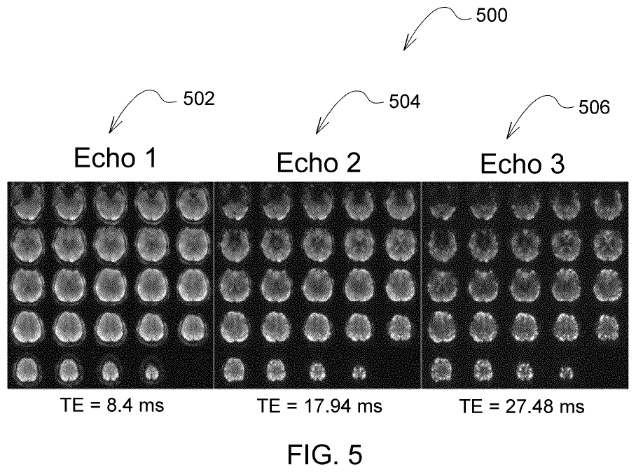

FIG. 5 illustrates raw images 500 obtained by three echoes of a multi-echo EPI in accordance with at least one example embodiment. FIG. 5 includes a first echo 502, a second echo 504, and a third echo 506. The raw images 500 were obtained from an in vivo test performed on adult male subjects with a 7 Tesla scanner using a pCASL sequence with 2D EPI readout and a Nova 32-ch coil. A pCASL labelling phase may last about 1.5 s with a post pCASL labelling phase delay of about 1.8 s. The raw images 500 were acquired at 3.5 mm isotropic resolution, axial FOV of 189 mm, and 24 slices. A TR for the above-described process is about 4.1 s and a matrix size for the raw images 500 is about 54×54. Thus, each image of each of the first echo 502, the second echo 504, and the third echo 506 of the raw images 500 includes 54 pixels in a horizontal direction and 54 pixels in a vertical direction. A TR for the first echo 502 was about 8.4 ms, a TR for the second echo 504 was about 17.94 ms, and a TR for the third echo 506 was about 27.48 ms. The TR for the second echo 504 is a time from the beginning of the first echo 502 to the end of the second echo 504 and the TR for the third echo 506 is a time from the beginning of the first echo 502 to the end of the third echo 506. There may be about 0.53 ms between each echo, a readout bandwidth may be about 2374 Hz/pixel and a phase encoding event may be three times accelerated.

As shown in FIG. 5, the images obtained during the third echo 506 may show less detail or may be considered images with less contrast than those of the first echo 502. Because the third echo 506 occurs after the first echo 502 and the second echo 504, it is obtained as a relaxation time is being approached. The relaxation is a T2* relaxation that is responsible for reduced signal amplitude as shown in the third echo 506 compared to the first echo 502 and the second echo 504. The relaxation time is a relaxation time of brain parenchyma or grey matter, which is approximately 20 ms. Thus, the raw images from the third echo 506 may have less contrast than raw images from the first echo 502 or the second echo 504 in at least one example embodiment which may result in the raw images from the third echo 506 having a lower SNR than raw images from the first echo 502 and the second echo 504.

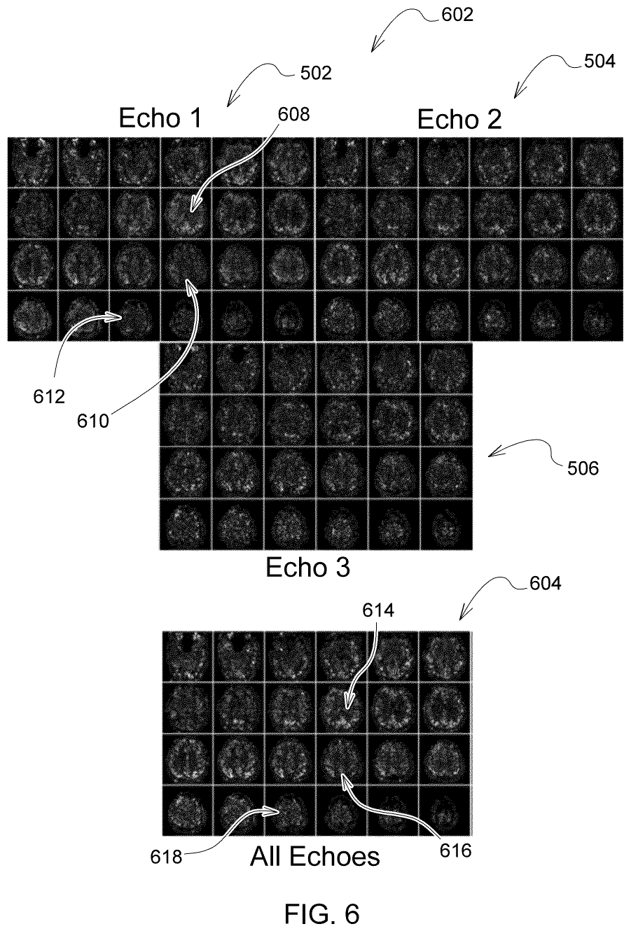

FIG. 6 illustrates perfusion weighted images 602 of the raw images 500 of FIG. 5. FIG. 6 also illustrates a weighted combination 604 of the perfusion weighted images 602 of each echo. In at least one example embodiment, the raw images 500 may be weighted to obtain perfusion weighted images 602. The perfusion weighted images 602 may be weighted to favor images that have a higher SNR. Thus, images from the first echo 502 may be weighted higher than those from the second echo 504 and both the images from the first echo 502 and the second echo 504 may be weighted higher than those from the third echo 506. The weighted combination 604 of the perfusion weighted images 602 of each echo may be a weighted combination of each respective image from each echo.

In at least one example embodiment, there may be a time constant that is used for weighting the raw images 500. For example, at the time of the first echo 502, the signal strength may be considered one. At the time of the second echo 504, the signal strength may be less than one. For example, it may be 60% of the signal strength at the time of the first echo 502. Thus, the images from the second echo 504 may be weighted by 0.6. Similarly, the signal strength at a time of the third echo 506 may be about 30% of the signal strength at the time of the first echo 502. Thus, the images from the third echo 506 may be weighted by 0.3. The signal strength of the echoes may be decreasing with time based on the relaxation time as discussed above.

Although the raw images 500 may be weighted as described above, the perfusion weighted images 602 of FIG. 6 each have a weight of one. In at least one example embodiment, each of the weights based on the signals at each of the echoes may be applied when determining the weighted combination 604 of the perfusion weighted images 602.

The weighted combination 604 of the perfusion weighted images 602 of each echo may be images with a better signal than any of the echoes alone. For example, the first arrow 608, the second arrow 610, and the third arrow 612 point out regions of the perfusion weighed images 602 of the first echo 502. A corresponding first arrow 614, a corresponding second arrow 616, and a corresponding arrow 618 point to the same areas from the perfusion weighted images 602 of the first echo 502 in the weighted combination 604 of the perfusion weighted images 602 of each echo. Each region of the weighted combination 604 of the perfusion weighted images 602 of each echo includes more signal than that of the first echo 502 which provides a clearer image of the imaged volume.

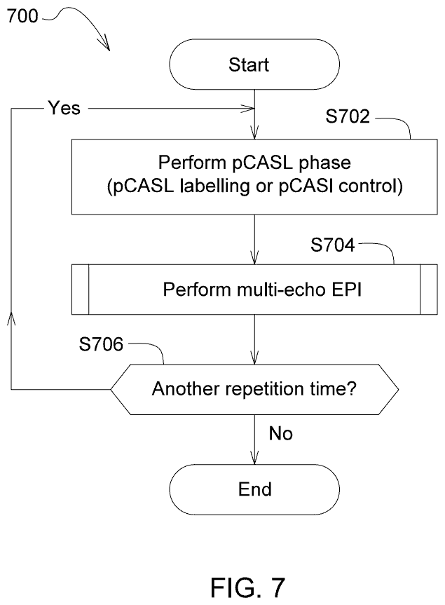

FIG. 7 illustrates a method 700 for performing MR imaging using ASL in accordance with at least one example embodiment.

Referring to FIG. 7, the method 700 may begin at S702 where a pCASL phase is performed. The at least one processor 30 may cause the system 10 to perform the pCASL phase in at least one example embodiment. The pCASL phase may be either a pCASL labelling phase or a pCASL control phase. As described above, alternating TRs may alternate which pCASL phase is performed. Thus, a first TR may include a pCASL labelling phase while a second TR may include a pCASL control phase.

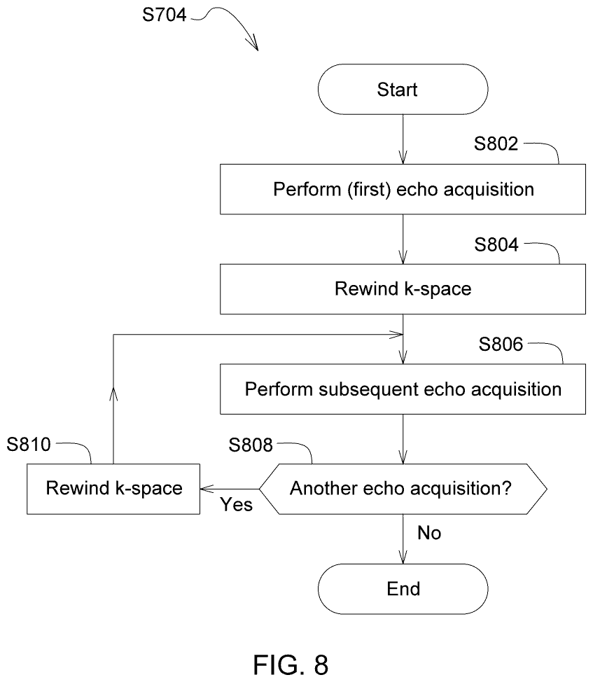

At S704, multi-echo imaging is performed. The at least one processor 30 may cause the system 10, in particular, the acquisition device 20, to perform the multi-echo EPI in at least one example embodiment. Additional details of the performance of the multi-echo EPI are described below with reference to FIG. 8.

At conditional step S706, the at least one processor 30 determines whether there is another repetition time (TR) to complete according to the MR sequence or protocol being executed. If there is another repetition time, the method 700 returns to S702 where a next pCASL phase is performed. If there is not another repetition time, the method 700 may terminate or end.

FIG. 8 illustrates an example embodiment of a method for performing multi-echo EPI at S704 in FIG. 7.

Referring to FIG. 8, the step 704 may begin at S802 when a first echo acquisition is performed. The at least one processor 30 may cause the acquisition device 20 of the system 10 to perform the first echo of the multi-echo EPI in at least one example embodiment.

After the first echo is complete, the at least one processor 30 may rewind k-space at S804. Thus, the next echo may be configured to image an entire imaging volume so the imaging volume is the same for each echo of the multi-echo EPI.

At S806, the at least one processor 30 may cause the acquisition device 20 of the system 10 to perform a subsequent echo acquisition of the multi-echo EPI. The subsequent echo acquisition may be acquired substantially similar to the first echo acquisition of the multi-echo EPI.

At conditional step S808, the at least one processor 30 determines whether there is another echo acquisition to be performed based on the MR sequence or protocol being executed. If there is another echo acquisition, at S810, the at least one processor 30 rewinds k-space and returns to S806 to perform a subsequent echo acquisition.

Returning to S808, if there is not another echo acquisition to be performed, the multi-echo EPI may terminate or end.

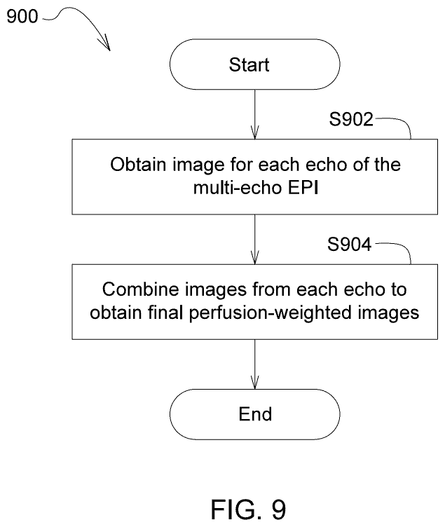

FIG. 9 illustrates a method 900 of determining a perfusion-weighted image in accordance with at least one example embodiment.

Referring to FIG. 9, at S902, the at least one processor 30 may cause the acquisition device 20 of the system 10 to obtain an image for each echo of the multi-echo EPI. The images may first be raw images such as the raw images 500 of FIG. 5. The raw images may then be perfusion weighted as described above with regard to the perfusion weighted images 602 of FIG. 6.

At S904, the images may be combined to obtain final perfusion-weighted images. The final perfusion-weighted images may be a combination of perfusion-weighted images from each echo of a multi-echo EPI as described above. The final perfusion-weighted images may be images with higher SNR and may have fewer distortions than images obtained from single echo EPI or other imaging methods associated with pCASL procedures.

The above-described systems and methods provide improved imaging procedures for use with pCASL. The multi-echo EPI imaging acquisitions described above provide improved imaging methods by maintaining a SNR of previous imaging techniques while also providing images with fewer distortions due to the higher effective phase encoding bandwidth.

Example embodiments have been disclosed herein, it should be understood that other variations may be possible. Such variations are not to be regarded as a departure from the spirit and scope of the present disclosure, and all such modifications as would be obvious to one skilled in the art are intended to be included within the scope of the following claims.

### NON-LIMITING ILLUSTRATIVE EMBODIMENTS

The following is a list of non-limiting illustrative embodiments disclosed herein:

Illustrative embodiment 1 includes a method for performing magnetic resonance (“MR”) imaging using arterial-spin labeling (“ASL”), the method comprising: performing a pseudo-continuous ASL (“pCASL”) phase, the pCASL phase being at least one of a pCASL labelling phase or a pCASL control phase; and performing an image acquisition after the pCASL phase using multi-echo echo planar imaging (“EPI”).

Illustrative embodiment 2 includes the method of illustrative embodiment 1, wherein the multi-echo EPI includes at least two echo acquisitions.

Illustrative embodiment 3 includes the method of any one of the preceding illustrative embodiments, wherein the performing the image acquisition after the pCASL phase using the multi-echo EPI comprises: performing a first echo acquisition; rewinding k-space after the first echo acquisition; and performing a second echo acquisition.

Illustrative embodiment 4 includes the method of any one of the preceding illustrative embodiments, wherein a readout (“RO”) gradient is continuous across all echoes of the multi-echo EPI.

Illustrative embodiment 5 includes the method of any one of the preceding illustrative embodiments, further comprising: obtaining an image for each echo of the multi-echo EPI; and combining the images for each echo of the multi-echo EPI to obtain a perfusion-weighted image.

Illustrative embodiment 6 includes the method of illustrative embodiment 5, wherein the perfusion-weighted image is a weighted combination of the images from each echo of the image acquisition using multi-echo EPI.

Illustrative embodiment 7 includes the method of illustrative embodiment 6, wherein an image from a first echo acquisition is weighed higher than other images of the multi-echo EPI for the perfusion-weighted image.

Illustrative embodiment 8 includes a system for performing magnetic resonance (“MR”) imaging using arterial-spin labeling (“ASL”), the system comprising: at least one memory configured to store instructions; and at least one processor configured to execute the instructions to cause the system to, perform a pseudo-continuous ASL (“pCASL”) phase, the pCASL phase being at least one of a pCASL labelling phase or a pCASL control phase; and perform an image acquisition after the pCASL phase using multi-echo echo planar imaging (“EPI”).

Illustrative embodiment 9 includes the system of illustrative embodiment 8, wherein the multi-echo EPI includes at least two echo acquisitions.

Illustrative embodiment 10 includes the system of any one of illustrative embodiments 8-9, wherein the processor is configured to cause the system to, for the performing the image acquisition after the pCASL using the multi-echo EPI, perform a first echo acquisition; rewind k-space after the first echo acquisition; and perform a second echo acquisition.

Illustrative embodiment 11 includes the system of any one of illustrative embodiments 8-10, wherein a readout (“RO”) gradient is continuous across all echoes of the multi-echo EPI.

Illustrative embodiment 12 includes the system of any one of illustrative embodiments 8-11, wherein the processor is further configured to cause the system to: obtain an image for each echo of the multi-echo EPI; and combine the images for each echo of the multi-echo EPI to obtain a perfusion-weighted image.

Illustrative embodiment 13 includes the system of illustrative embodiment 12, wherein the perfusion-weighted image is a weighted combination of the images from each echo of the image acquisition using multi-echo EPI.

Illustrative embodiment 14 includes the system of illustrative embodiment 13, wherein an image from a first echo acquisition is weighed higher than other images of the multi-echo EPI for the perfusion-weighted image.

Illustrative embodiment 15 includes a non-transitory computer readable medium storing computer-executable instruction that, when executed by at least one processor of a system, cause the system to perform a method for performing magnetic resonance (“MR”) imaging using arterial-spin labeling (“ASL”), the method comprising: performing a pseudo-continuous ASL (“pCASL”) phase, the pCASL phase being at least one of a pCASL labelling phase or a pCASL control phase; and performing an image acquisition after the pCASL phase using multi-echo echo planar imaging (“EPI”).

Illustrative embodiment 16 includes the non-transitory computer readable medium of illustrative embodiment 15, wherein the multi-echo EPI includes at least two echo acquisitions.

Illustrative embodiment 17 includes the non-transitory computer readable medium of illustrative embodiment 15, wherein the performing the image acquisition after the pCASL phase using the multi-echo EPI comprises: performing a first echo acquisition; rewinding k-space after the first echo acquisition; and performing a second echo acquisition.

Illustrative embodiment 18 includes the non-transitory computer readable medium of illustrative embodiment 15, wherein a readout (“RO”) gradient is continuous across all echoes of the multi-echo EPI.

Illustrative embodiment 19 includes the non-transitory computer readable medium of illustrative embodiment 15, wherein the method further comprises: obtaining an image for each echo of the multi-echo EPI; and combining the images for each echo of the multi-echo EPI to obtain a perfusion-weighted image.

Illustrative embodiment 20 includes the non-transitory computer readable medium of illustrative embodiment 19, wherein the perfusion-weighted image is a weighted combination of the images from each echo of the image acquisition using multi-echo EPI and an image from a first echo acquisition is weighed higher than other images of the multi-echo EPI for the perfusion-weighted image.

We claim:

1. A method for performing magnetic resonance (“MR”) imaging using arterial-spin labeling (“ASL”), the method comprising:
performing a pseudo-continuous ASL (“pCASL”) phase, the pCASL phase being at least one of a pCASL labelling phase or a pCASL control phase; and
performing an image acquisition after the pCASL phase using multi-echo echo planar imaging (“EPI”).

2. The method of claim 1, wherein the multi-echo EPI includes at least two echo acquisitions.

3. The method of claim 1, wherein the performing the image acquisition after the pCASL phase using the multi-echo EPI comprises:
performing a first echo acquisition;
rewinding k-space after the first echo acquisition; and
performing a second echo acquisition.

4. The method of claim 1, wherein a readout (“RO”) gradient is continuous across all echoes of the multi-echo EPI.

5. The method of claim 1, further comprising:
obtaining an image for each echo of the multi-echo EPI; and
combining the images for each echo of the multi-echo EPI to obtain a perfusion-weighted image.

6. The method of claim 5, wherein the perfusion-weighted image is a weighted combination of the images from each echo of the image acquisition using multi-echo EPI.

7. The method of claim 6, wherein an image from a first echo acquisition is weighed higher than other images of the multi-echo EPI for the perfusion-weighted image.

8. A system for performing magnetic resonance (“MR”) imaging using arterial-spin labeling (“ASL”), the system comprising:
at least one memory configured to store instructions; and
at least one processor configured to execute the instructions to cause the system to,
perform a pseudo-continuous ASL (“pCASL”) phase, the pCASL phase being at least one of a pCASL labelling phase or a pCASL control phase; and
perform an image acquisition after the pCASL phase using multi-echo echo planar imaging (“EPI”).

9. The system of claim 8, wherein the multi-echo EPI includes at least two echo acquisitions.

10. The system of claim 8, wherein the processor is configured to cause the system to, for the performing the image acquisition after the pCASL using the multi-echo EPI,
perform a first echo acquisition;
rewind k-space after the first echo acquisition; and
perform a second echo acquisition.

11. The system of claim 8, wherein a readout (“RO”) gradient is continuous across all echoes of the multi-echo EPI.

12. The system of claim 8, wherein the processor is further configured to cause the system to:
obtain an image for each echo of the multi-echo EPI; and
combine the images for each echo of the multi-echo EPI to obtain a perfusion-weighted image.

13. The system of claim 12, wherein the perfusion-weighted image is a weighted combination of the images from each echo of the image acquisition using multi-echo EPI.

14. The system of claim 13, wherein an image from a first echo acquisition is weighed higher than other images of the multi-echo EPI for the perfusion-weighted image.

15. A non-transitory computer readable medium storing computer-executable instruction that, when executed by at least one processor of a system, cause the system to perform a method for performing magnetic resonance (“MR”) imaging using arterial-spin labeling (“ASL”), the method comprising:
performing a pseudo-continuous ASL (“pCASL”) phase, the pCASL phase being at least one of a pCASL labelling phase or a pCASL control phase; and
performing an image acquisition after the pCASL phase using multi-echo echo planar imaging (“EPI”).

16. The non-transitory computer readable medium of claim 15, wherein the multi-echo EPI includes at least two echo acquisitions.

17. The non-transitory computer readable medium of claim 15, wherein the performing the image acquisition after the pCASL phase using the multi-echo EPI comprises:
performing a first echo acquisition;
rewinding k-space after the first echo acquisition; and
performing a second echo acquisition.

18. The non-transitory computer readable medium of claim 15, wherein a readout (“RO”) gradient is continuous across all echoes of the multi-echo EPI.

19. The non-transitory computer readable medium of claim 15, wherein the method further comprises:
obtaining an image for each echo of the multi-echo EPI; and
combining the images for each echo of the multi-echo EPI to obtain a perfusion-weighted image.

20. The non-transitory computer readable medium of claim 19, wherein the perfusion-weighted image is a weighted combination of the images from each echo of the image acquisition using multi-echo EPI and an image from a first echo acquisition is weighed higher than other images of the multi-echo EPI for the perfusion-weighted image.
